(19) United States
(12) Patent Application Publication
(10) Pub. No.: US 2008/0102701 A1
(43) Pub. Date: May 1, 2008

(54) Connector with Shield, and Circuit Board Device

(75) Inventors: Hiroyuki Suzuki, Kanagawa (JP); Kiyoshi Nakanishi, Kanagawa (JP); Ken Muramatsu, Kanagawa (JP); Tooru Saitou, Tokyo (JP); Noriaki Amano, Kanagawa (JP); Masahiro Ono, Osaka (JP); Shigeru Kondou, Osaka (JP)

Correspondence Address: RATNERPRESTIA, P.O. BOX 980, VALLEY FORGE, PA, 19482, US

(73) Assignee: MATSUSHITA ELECTRIC INDUSTRIAL CO., LTD., Osaka (JP)

(21) Appl. No.: 11/719,035

(22) PCT Filed: Nov. 22, 2005
(86) PCT No.: PCT/JP05/21941

§ 371 Date: May 10, 2007

(30) Foreign Application Priority Data
Nov. 24, 2004 (JP) JP 2004-338454

(51) Int. Cl. H01R 13/648; H05K 1/11

(52) U.S. Cl. 439/608; 361/784

(57) ABSTRACT

A first printed board on which a ground pattern is provided and an electronic part is mounted and a second printed board on which a ground pattern is provided and an electronic part is mounted are oppositely arranged, and circuits of the first printed board and the second printed board are connected by a connector with a frame-like shield. In the connector with a shield, a frame body is formed of an insulator such as a resin, a connection terminal is provided inside the frame body, and a conductor is provided on the entire outer periphery of the frame body. In the conductor, the shield is formed by both the ground pattern of the first printed board and the ground pattern of the second printed board. The frame body shields the electronic parts.

THIS APPLICATION IS A U.S. NATIONAL PHASE APPLICATION OF PCT INTERNATIONAL APPLICATION PCT/JP2005/021941.

### TECHNICAL FIELD

The present invention relates to a connector with a shield capable of not only forming a shield between oppositely disposed printed circuit boards but also connecting a connection terminal of the printed circuit boards. The present invention also relates to a circuit board device using the connector with a shield.

### BACKGROUND ART

As a method of shielding a circuit and an electronic part mounted on a printed circuit board from other components, for example, Japanese Patent Unexamined Publication No. H10-41669 discloses a shield device. The shield device has a shield case of a box shape with one side of the six sides open. The case is disposed at a printed circuit board so as to cover the board. The ground of the printed circuit board is connected to the shield case.

As another example, Japanese Patent Unexamined Publication No. H08-139488 discloses a method of forming a shield between oppositely disposed printed circuit boards. According to the method, a ground pattern is disposed at a part of a printed circuit board facing an electronic part or a circuit that can be a noise source. In addition, a metallic chassis of a square frame shape is disposed between the boards so as to shield the electronic parts and circuits from other components.

FIG. 11A and FIG. 11B show conventional structure that forms a shield between printed circuit boards and connects the connection terminals of the circuit boards. In FIG. 11A and FIG. 11B, connection terminals (not shown) of printed circuit boards 1 and 2 are connected via terminals 107 of connector members 10 and 11. Box-like shield case 8, which is disposed at printed circuit board 2 so as to cover electronic parts and the like, is connected to ground pattern 9b at printed circuit board 2 via ground terminal 107a. Shield case 8 and ground pattern 9b form a shield, thereby shielding noise caused by electronic part 6b from going outside.

The conventional structure, however, has some inconveniencies as follows:

To connect the circuits between oppositely disposed printed circuit boards, shield case 8 and connector members 10, 11 have to be individually disposed as a separate structure. Due to the restraint above, a printed circuit board needs the area for mounting connector members 10 and 11, in addition to the area for mounting shield case 8, electronic part 6b and the circuit for connecting electronic part 6b. This has been an obstacle to downsizing of the circuit board device.

Each of connector members 10 and 11 has limited number of terminals, which limits the number of circuits to be connected. Besides, increasing the number of the terminals of the connector members increases density in wiring in the periphery of the connector members. It has invited difficulty in circuit design on a printed circuit board.

When an electronic circuit needs shielding, components to be shielded have to be brought together on either one of the oppositely disposed circuit boards. The fact adds restrictions on circuit design.

### DISCLOSURE OF THE INVENTION

To address the problems above, the connector with a shield of the present invention contains a frame body, a conductor disposed around the frame body and connection terminals. The frame body, which is made of insulating material, such as resin, surrounds a predetermined area between a pair of printed circuit boards confronting with each other. The connection terminals for connecting circuits on the pair of printed circuit boards are disposed at the frame body. The aforementioned structure where the connection terminals are disposed at a shield allows the circuit board device to form compact. Besides, the structure with no use of a connector member eliminates restrictions on the number of connection terminals, thereby establishing connections in a large number of circuits between the printed circuit boards. Furthermore, the connection terminals are not necessarily concentrated at an area but can be disposed at a spread-out arrangement over the frame body of the insulating material. This increases flexibility in wiring layout of the circuits on the printed circuit boards, enhancing easy circuit design. The connection terminals connect a pair of the printed circuit boards, allowing electronic parts with the need for being shielded to be disposed at both the printed circuit boards. This reduces restrictions on circuit design, providing a flexible, optimum structure.

In accordance with an aspect of the present invention, the connector with a shield is so formed that the conductor is disposed at the outer periphery of the frame body and the connection terminals are disposed at least at one inner side of the frame body. The structure above establishes electrical connections of the circuits disposed inside the shield between the pair of printed circuit boards, allowing electronic parts that need for being shielded to be disposed at both the printed circuit boards. The structure, since the connection terminals are disposed within the shield, prevents noise and electromagnetic waves that can be caused by the connection terminals from going outside the shield. This enhances reliability in operations of the circuits outside the shield.

In accordance with another aspect of the present invention, the connector with a shield is so formed that the conductor is disposed at the inner periphery of the frame body and the connection terminals are disposed at least one at outer side of the frame body. The structure above establishes electrical connections of the circuits disposed outside the shield between the pair of printed circuit boards, allowing required electronic parts to be disposed outside the shield on both the printed circuit boards. The structure, since the connection terminals are disposed outside the shield, prevents the connection terminals from interference of noise and electromagnetic waves generated in the shield.

In accordance with still another aspect of the present invention, the connector with a shield is so formed that the conductor is disposed at the outer periphery of the frame body and the connection terminals are disposed inside the frame body. The structure above establishes electrical connections of the circuits disposed inside the shield between the pair of printed circuit boards. The structure, since the connection terminals are disposed within the shield, prevents noise and electromagnetic waves that can be caused by the connection terminals from going outside the shield. The connection terminals, since disposed in the insulating material, can avoid contact with electronic parts disposed inside the shield.

In accordance with yet another aspect of the present invention, the connector with a shield is so formed that a connection terminal for connecting the inside and the outside of the frame body is disposed at least at one side of the frame body. The structure allows the circuits in the shield to have connection to the outside of the shield. Difference in wiring methods, for example, surface-layer wiring or inner-layer wiring of a printed circuit board or cable wiring, can invite unstable impedance-matching, which sometimes results in signal deterioration. However, the structure of the embodiment not only prevents the aforementioned problem but also allows a printed circuit board to have a minimized number of layers. That is, the structure of the embodiment connects between the circuits disposed in the shield and the circuits outside the shield, with high shielding effect maintained.

In accordance with still another aspect of the present invention, the connector with a shield is so formed that an opening is disposed at least at one side of the frame body. The structure allows the circuits disposed in the shield to connect, via a cable or the like, to the outside of the shield. Besides, the opening allows electronic parts to pass through from the inside to the outside of the shield, enhancing flexibility in circuit design.

In accordance with another aspect of the present invention, the connector with a shield can be divided into the upper-half and the lower-half and a connection terminal is disposed at the joint section of the two halves. With the structure, prior to establishing electrical connections, required electronic parts and each half of the connector are mounted on each printed circuit board. Attaching the pair of printed circuit boards connects the connection terminal and forms a shield. The pair of the boards attached with each other can be divided into separate two boards. By virtue of the dividable structure, the electronic parts and circuits can be easily adjusted as necessary.

A circuit board device of the present invention is so formed that a ground pattern is formed on a pair of printed circuit boards and the ground pattern is surrounded by a connector with a shield for obtaining shielding effect. The structure in which a connection terminal is disposed in a shield allows the circuit board device to be compact. Besides, the structure with no use of a connector member eliminates restrictions on the number of connection terminals, thereby establishing connections in a large number of circuits between the printed circuit boards. Furthermore, the connection terminals are not concentrated at an area but can be disposed at a spread-out arrangement over the frame body of the insulating material. This increases flexibility in wiring layout of the circuits on the printed circuit boards, enhancing easy circuit design. Besides, the connection terminals connect a pair of the printed circuit boards, allowing electronic parts with the need for being shielded to be disposed at both the printed circuit boards. This reduces restrictions on circuit design, providing a flexible, optimum structure.

### BRIEF DESCRIPTION OF THE DRAWINGS

FIG. 1A is a perspective view of a circuit board device having a connector with a shield in accordance with a first exemplary embodiment of the present invention.

FIG. 1B is a section view of the circuit board device in accordance with the first exemplary embodiment.

FIG. 1C is a section view of the connector with a shield in accordance with the first exemplary embodiment.

FIG. 2A is a perspective view of a circuit board device having a connector with a shield in accordance with a second exemplary embodiment of the present invention.

FIG. 2B is a section view of the circuit board device in accordance with the second exemplary embodiment.

FIG. 2C is a section view of the connector with a shield in accordance with the second exemplary embodiment.

FIG. 3A is a section view of a connector with a shield in accordance with a third exemplary embodiment.

FIG. 3B is a section view of the circuit board device in accordance with a third exemplary embodiment of the present invention.

FIG. 4A is an exploded perspective view of a circuit board device in accordance with a fourth exemplary embodiment of the present invention.

FIG. 4B is a partially shown sectional view of the circuit board device in accordance with the fourth exemplary embodiment.

FIG. 5A is an exploded perspective view of a circuit board device in accordance with a fifth exemplary embodiment of the present invention.

FIG. 5B is a partially shown sectional view of the circuit board device in accordance with the fifth exemplary embodiment.

FIG. 6A is an exploded perspective view of a circuit board device in accordance with a sixth exemplary embodiment of the present invention.

FIG. 6B is a partially shown sectional view of the circuit board device in accordance with the sixth exemplary embodiment.

FIG. 7A is a perspective view of a connector with a shield in accordance with a seventh exemplary embodiment of the present invention.

FIG. 7B is a partially shown sectional view of the circuit board device in accordance with the seventh exemplary embodiment.

FIG. 8A is a perspective view of a connector with a shield in accordance with the seventh exemplary embodiment of the present invention.

FIG. 8B is a partially shown sectional view of the circuit board device in accordance with the seventh exemplary embodiment.

FIG. 9A is a perspective view of a connector with a shield in accordance with an eighth exemplary embodiment of the present invention.

FIG. 9B is a partially shown sectional view of the circuit board device in accordance with the eighth exemplary embodiment.

FIG. 10A is a perspective view of a connector with a shield in accordance with the eighth exemplary embodiment of the present invention.

FIG. 10B is a partially shown sectional view of the circuit board device in accordance with the eighth exemplary embodiment.

FIG. 11A is a perspective view of a conventional circuit board device.

FIG. 11B is a partially shown sectional view of the conventional circuit board device.

### DETAILED DESCRIPTION OF CARRYING OUT OF THE INVENTION

The exemplary embodiments of the present invention are described hereinafter with reference to the accompanying drawings.

### First Exemplary Embodiment

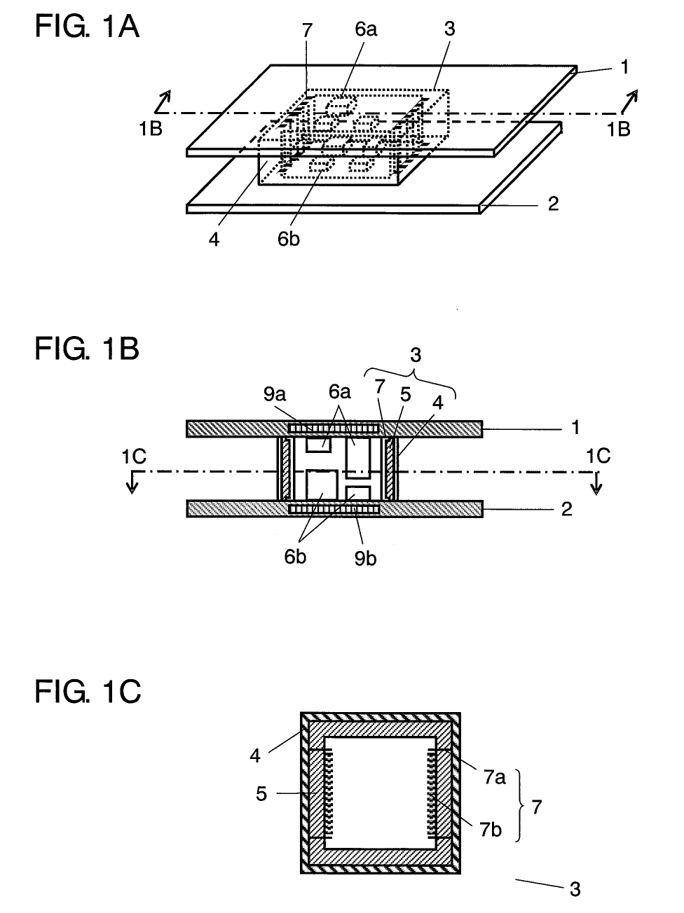

Each of FIGS. 1A, 1B, and 1C is a perspective view and section views of a circuit board device having a connector with a shield; FIG. 1A is a perspective view of a circuit board device formed of a connector with a shield and a pair of printed circuit boards; FIG. 1B shows a section taken along line 1B-1B of the circuit board device of FIG. 1A; and FIG. 1C is a partially shown section taken along line 1C-1C of the connector with a shield of FIG. 1B.

In FIG. 1A, printed circuit boards 1 and 2 are situated in a parallel arrangement. Electronic part 6a is disposed at the surface of printed circuit board 1 facing printed circuit board 2. Electronic part 6b is disposed at the surface of printed circuit board 2 so as to face electronic part 6a. In FIG. 1B, ground pattern 9a is formed on printed circuit board 1 and electronic part 6a is disposed at board 1 so as to stay within the bounds of ground pattern 9a. On the other hand, ground pattern 9b is formed on printed circuit board 2 and electronic part 6b is disposed at board 2 so as to stay within the bounds of ground pattern 9b. Connector 3 having a square frame body is disposed between printed circuit boards 1 and 2 so as to surround ground patterns 9a and 9b.

In FIG. 1C, connector 3 with a shield has square frame body 5 as a main structure. Frame body 5 is made of resin or other insulating material. Conductor 4 is disposed over the outer periphery of frame body 5. Connection terminals 7 are disposed at two inner sides facing with each other of frame body 5. Each of connection terminals 7 is formed of ground terminal 7a and signal terminal 7b. Signal terminal 7b connects the circuits of between printed circuit boards 1 and 2. Ground terminal 7a is connected to a ground circuit (not shown) of printed circuit board 1 or printed circuit board 2. Ground terminal 7 runs inside frame body 5 and is connected to conductor 4. Ground patterns 9a, 9b and conductor 4 form a shield. With the structure, connector 3 with a shield prevents noise or electromagnetic waves, which can be caused by the circuits and electronic parts 6a, 6b mounted on circuit board 1, 2 and signal terminal 7b, from going outside. Therefore, an electronic part disposed outside the shield has no ill effect from the inside of the shield and functions normally. As another advantage, connector 3 with a shield serves as a support member of printed circuit board 2.

As described above, signal terminals 7b are disposed at the two sides of frame body 5. This provides the circuit layout in the shield with high flexibility.

Although frame body 5 is formed into a square shape in the embodiment, it is not limited thereto: frame body 5 can be shaped into other polygons or a curved structure as long as it surrounds electronic circuits 6a and 6b. Connection terminals 7 can be situated anywhere in the inner periphery of the frame body.

Connector 3 with a shield is attached to printed circuit boards 1 and 2 in either of the followings: the attachment with a clearance left at a joint section; or the attachment with no clearance left at a joint section. It will be understood that higher shield effect is expected in the tight attachment with no clearance.

Connector 3 with a shield and printed circuit boards 1, 2 can be secured by adhesive, by soldering or by fitted-in attachment.

### Second Exemplary Embodiment

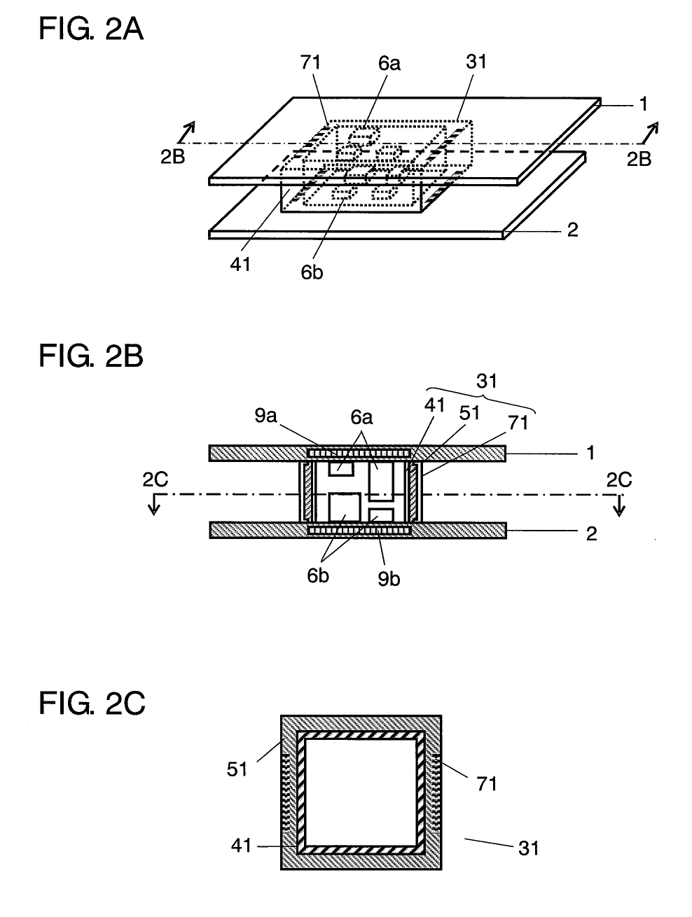

FIG. 2A shows a perspective view and FIGS. 2B and 2C show section views of circuit board device having a connector with a shield in accordance with the second exemplary embodiment of the present invention. FIG. 2A is a perspective view of a circuit board device formed of a connector with a shield and a pair of printed circuit boards. FIG. 2B shows a section taken along line 2B-2B of the circuit board device of FIG. 2A. FIG. 2C shows a section taken along line 2C-2C of the connector with a shield of FIG. 2B. Throughout the drawings above, like parts are identified by the same reference marks as in each of FIGS. 1A, 1B and 1C and the detailed description thereof will be omitted.

In FIG. 2C, connector 31 with a shield has square frame body 51 as a main structure. Frame body 51 is made of resin or other insulating materials. Connection terminals 71 are disposed at two outer sides in opposite arrangement of frame body 51. Connection terminals 71 connect the circuits between printed circuit boards 1 and 2 outside connector 31 with a shield. Conductor 41 is disposed over the inner periphery of frame body 51. Conductor 41 is connected to a ground circuit (not shown) of printed circuit board 1 or printed circuit board 2. Ground patterns 9a, 9b and conductor 41 form a shield. With the structure, connector 31 with a shield prevents noise or electromagnetic waves, which can be caused by the circuits and electronic parts 6a, 6b mounted on circuit board 1, 2, from going outside. Therefore, an electronic part disposed outside the shield has no ill effect from the inside of the shield and functions normally.

Connection terminals 71 are disposed at oppositely located two sides of frame body 51, whereby the circuits outside the shield on printed circuit boards 1 and 2 can be arranged with high flexibility.

Although frame body 51 is formed into a square shape in the embodiment, it is not limited thereto: frame body 51 can be shaped into other polygons or a curved structure as long as it surrounds electronic parts 6a and 6b. Connection terminals 71 can be situated anywhere in the outer periphery of the frame body.

Connector with a shield can be attached to printed circuit boards 1 and 2 in either way of the followings: the attachment with a clearance left at a joint section; or the attachment with no clearance left at a joint section. It will be understood that higher shield effect is expected in the tight attachment with no clearance.

### Third Exemplary Embodiment

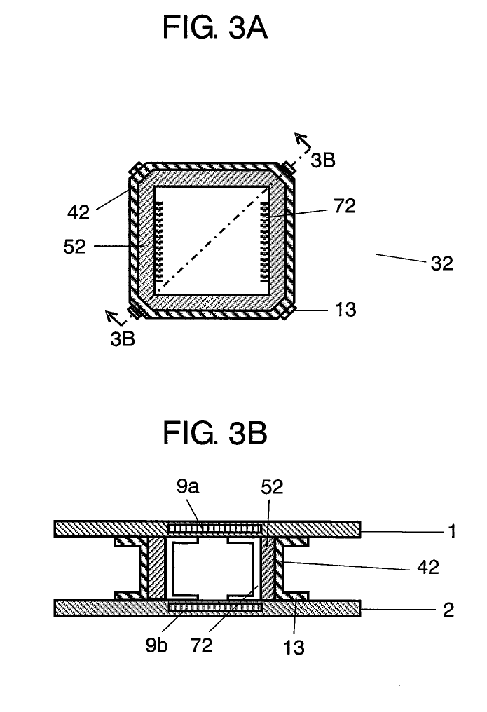

Each of FIGS. 3A and 3B is a section view of a connector with a shield in accordance with the third embodiment of the present invention. FIG. 3A shows a section parallel to an opening of connector 32 with a shield. Connector 32 with a shield has frame body 52 as a main structure. Frame body 52 is made of resin or other insulating material. Conductor 42 is disposed over the outer periphery of frame body 52. Connection terminals 72 are disposed at two inner sides of frame body 52. Frame body 52 has a square shape, with four corner rounded. Connection/reinforcement members 13 are disposed at the four rounded corners on conductor 42.

FIG. 3B shows a section taken along line 3B-3B of connector 32 with a shield of FIG. 3A, with the connector connected to printed circuit boards 1 and 2. Printed circuit board 1 has ground pattern 9a and printed circuit board 2 has ground pattern 9b. Each of connection/reinforcement members 13 is outwardly disposed at each corner section so as to have a right angle to the frame body of connector 32 and then attached to printed circuit boards 1 and 2. At least one of connection/reinforcement members 13 is connected to a ground terminal (not shown) of board 2 or board 2. Conductor 42, ground patterns 9a and 9b form a shield.

Connection/reinforcement members 13 enhance strength of attachment between connector 32 with a shield and printed circuit boards 1, 2. Disposing connection/reinforcement members 13 on the rounded corner sections of frame body 52 saves a mounting space, contributing to a downsized circuit board device.

Connector 32 can be attached to printed circuit boards 1 and 2 in either way of the followings: the attachment with a clearance left at a joint section; or the attachment with no clearance left at a joint section. It will be understood that higher shield effect is expected in the tight attachment with no clearance.

### Fourth Exemplary Embodiment

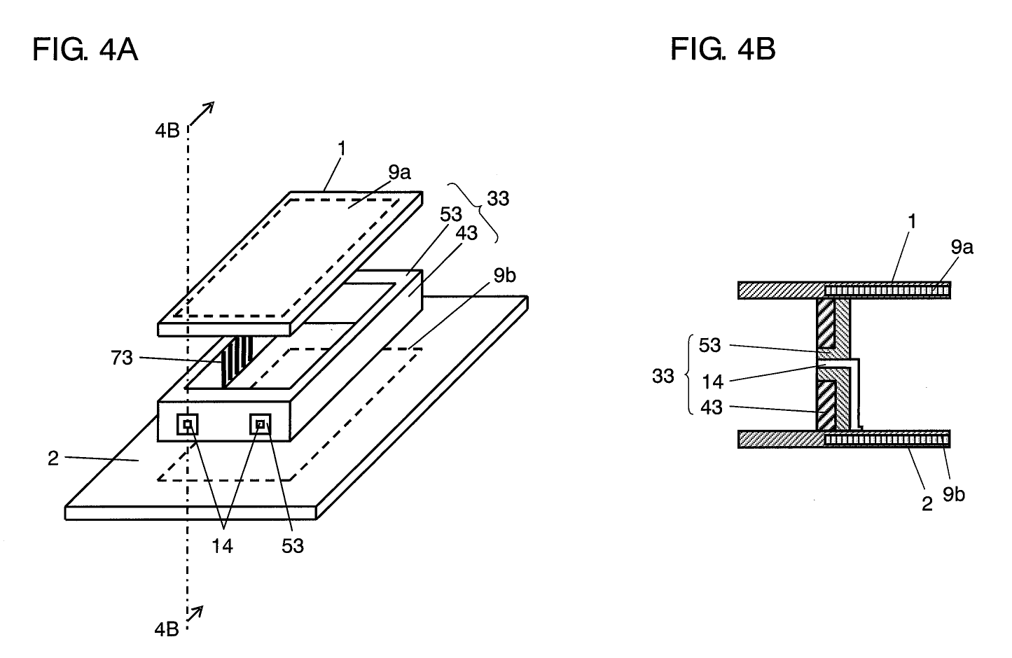

Each of FIGS. 4A and 4B is a perspective view and FIG. 4B is a partially shown section view of a circuit board device having a connector with a shield in accordance with the fourth exemplary embodiment of the present invention. FIG. 4A is an exploded perspective view of a circuit board device formed of a connector with a shield and a pair of printed circuit boards. FIG. 4B shows a section taken along line 4B-4B of the circuit board device of FIG. 4A.

In FIG. 4A, printed circuit boards 1 and 2 are situated in a parallel arrangement. Ground pattern 9a is disposed at printed circuit board 1 and ground pattern 9b is disposed at printed circuit board 2. Connector 33 with a shield of a square frame is disposed between the two boards so as to surround ground patterns 9a and 9b. Connector 33 with a shield has square frame body 53 as a main structure that is made of resin or other insulating materials. Conductor 43 is disposed over the outer periphery of frame body 53. Connection terminals 73 are disposed at an inner side of frame body 53.

As is shown in FIG. 4B, a hole is disposed at a side of frame body 53 in a manner that the periphery of the hole is not covered with conductor 43. With the structure, connection terminal 14 having connections to printed circuit board 2 can be passed through the hole. This establishes connections between the circuits inside connector 33 with a shield and the circuits outside the connector. Difference in wiring methods, for example, surface-layer wiring or inner-layer wiring of a printed circuit board or cable wiring, can invite unstable impedance-matching, which sometimes results in signal deterioration. However, the structure of the embodiment not only prevents the aforementioned problem but also allows a printed circuit board to have a minimized number of layers. That is, the structure of the embodiment connects between the circuits disposed in the shield and the circuits outside the shield, with high shielding effect maintained. Although connection terminal 14 is connected to printed circuit board 2 in the embodiment, it can be connected to printed circuit board 1.

### Fifth Exemplary Embodiment

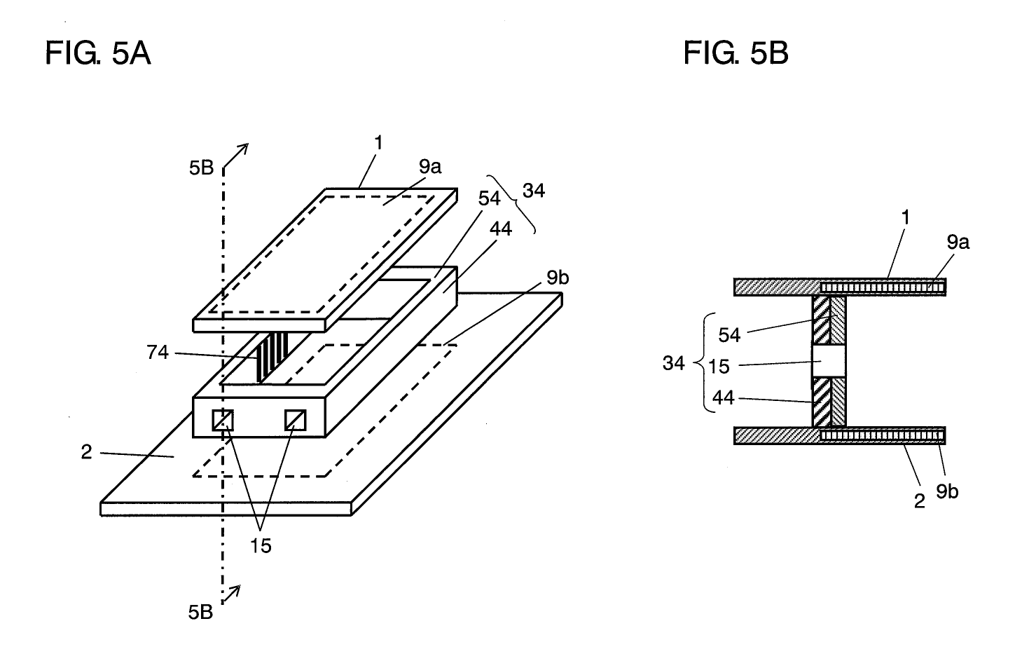

Each of FIGS. 5A and 5B is a perspective view and a partially shown section view of a circuit board device employing a connector with a shield in accordance with the fifth exemplary embodiment of the present invention. FIG. 5A is an exploded perspective view of a circuit board device formed of a connector with a shield and a pair of printed circuit boards. FIG. 5B shows a section taken along line 5B-5B of the circuit board device of FIG. 5A.

In FIG. 5A, printed circuit boards 1 and 2 are situated in a parallel arrangement. Ground pattern 9a is disposed at printed circuit board 1 and ground pattern 9b is disposed at printed circuit board 2. Connector 34 with a shield of a square frame shape is disposed between the two boards so as to surround ground patterns 9a and 9b. Connector 34 with a shield has square frame body 54 as a main structure that is made of resin or other insulating materials. Conductor 44 is disposed over the outer periphery of frame body 54. Connection terminals 74 are disposed at an inner side of frame body 54.

In FIG. 5B, opening 15 is disposed at a side of frame body 54. Passing a shielded wire or an electronic part through opening 15 establishes connections between the inside of connector 34 with a shield and the outside of the connector. This enhances flexibility in circuit design.

### Sixth Exemplary Embodiment

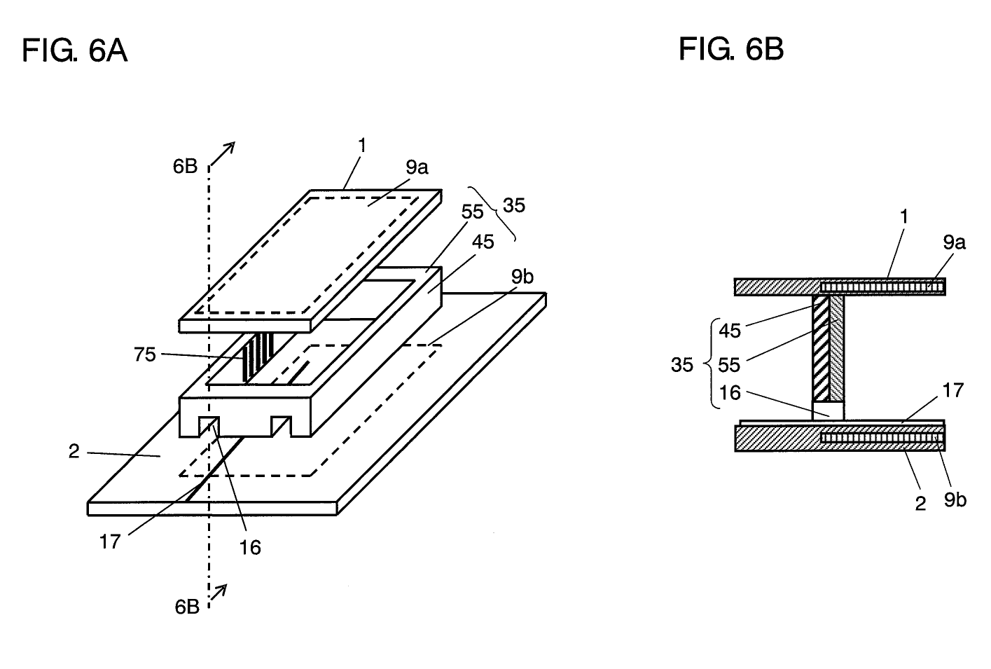

Each of FIGS. 6A and 6B is a perspective view and a partially shown section view of a circuit board device employing a connector with a shield in accordance with the sixth exemplary embodiment of the present invention. FIG. 6A is an exploded perspective view of a circuit board device formed of a connector with a shield and a pair of printed circuit boards. FIG. 6B shows a section taken along line 6B-6B of the circuit board device of FIG. 6A.

In FIG. 6A, printed circuit boards 1 and 2 are situated in a parallel arrangement. Ground pattern 9a is at on printed circuit board 1 and ground pattern 9b is disposed at printed circuit board 2. Circuit 17 is disposed at the surface of printed circuit board 2. Connector 35 with a shield of a square frame is disposed between the two boards so as to surround ground patterns 9a and 9b. Connector 35 with a shield has square frame body 55 as a main structure that is made of resin or other insulating materials. Conductor 45 is disposed over the outer periphery of frame body 55. Connection terminals 75 are disposed at an inner side of frame body 55.

In FIG. 6B, frame body 55 has notch 16 at the bottom connecting to printed circuit board 2 so as to pass through circuit 17 formed on board 2. That is, the surface-layer wiring on board 2 establishes connections between the circuits inside the shield and the circuits outside the shield, minimizing the number of layers of the printed circuit board. The structure also enhances flexibility in circuit design. Notch 16 can be disposed at the joint on the side of printed circuit board 1.

### Seventh Exemplary Embodiment

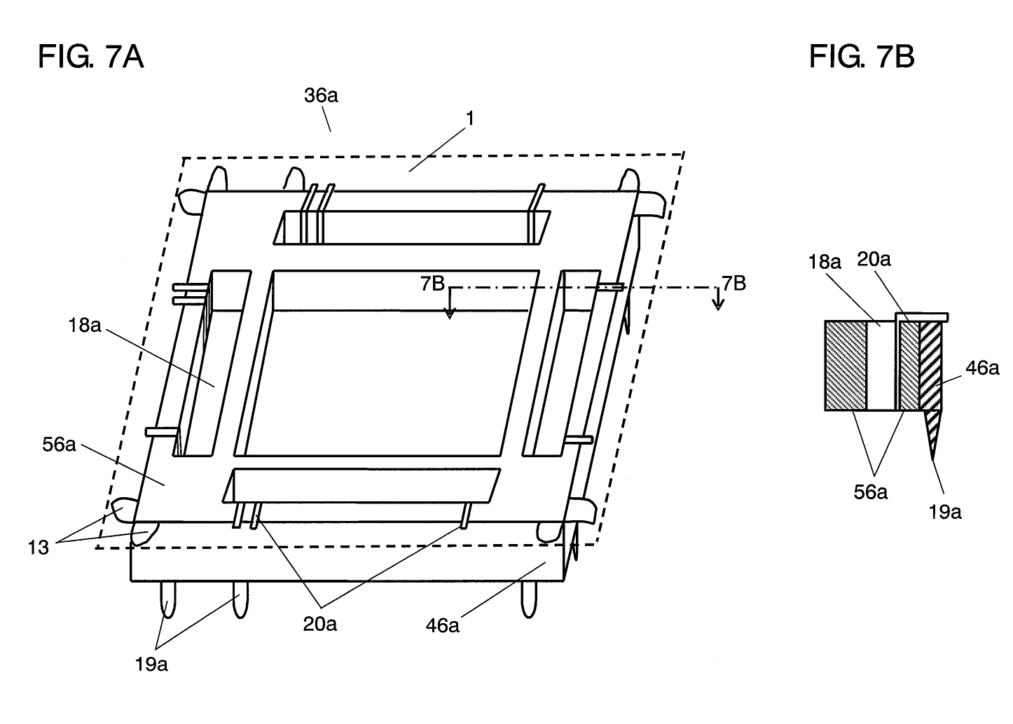

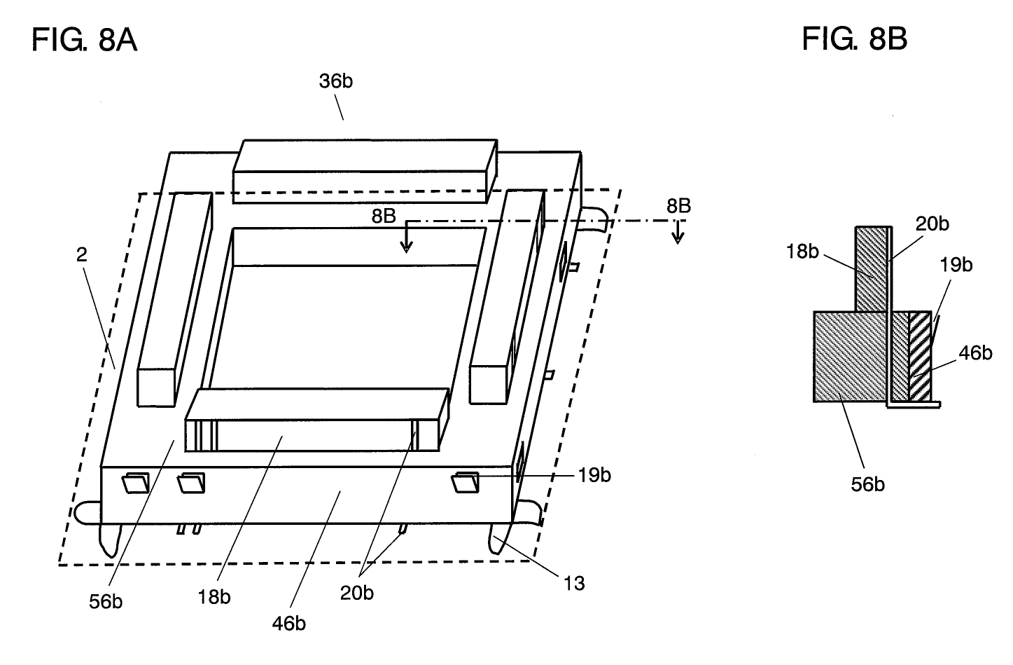

Each of FIGS. 7A, 7B, 8A and 8B is a perspective view and a partially shown section view of a connector with a shield in accordance with the seventh exemplary embodiment. The connector with a shield of the embodiment has a structure dividable into the upper half and the lower half. FIGS. 7A and 7B show upper connector 36a and FIGS. 8A and 8B show lower connector 36b.

Upper connector 36a of FIG. 7A, which is made of resin or other insulating materials, has square frame body 56a as a main structure. Conductor 46a is disposed over the outer periphery of frame body 56a. Conductor 46a has connection/reinforcement terminals 13 at each corner of the frame body having a contact with printed circuit board 1. Connection/reinforcement terminals 13 strengthen connections between upper connector 36a and printed circuit board 1 through the ground. Projections 19a are disposed at the side that makes contact with lower connector 36b.

FIG. 7B is a partially shown section view, taken along line 7B-7B, of upper connector 36a of FIG. 7A. Frame body 56a has recesses 18a on the side that makes contact with lower connector 36b. Recesses 18a have connection terminals 20a. Each of connection terminals 20a extends from the inner side of each recess to the surface that makes contact with printed circuit board 1. Although recesses 18a are formed into a through-hole in the embodiment, it is not limited thereto. Recesses 18a can be formed into a socket-like shape.

On the other hand, lower connector 36b of FIG. 8A, which is made of resin or other insulating materials, has square frame body 56b as a main structure. Conductor 46b is disposed over the outer periphery of frame body 56b. Conductor 46b has connection/reinforcement terminals 13 at each corner of the frame body having a contact with printed circuit board 2. Connection/reinforcement terminals 13 strengthen connections between lower connector 36b and printed circuit board 2 through the ground. Projection sockets 19b are disposed at the side that makes contact with upper connector 36a so as to fit with projections 19a of upper connector 36a.

FIG. 8B is a partially shown section view, taken along line 8B-8B, of lower connector 36b of FIG. 8A. Frame body 56b has bumps 18b on the side that makes contact with upper connector 36a. Each of bumps 18b fits in each of recesses 18a of upper connector 36a. Connection terminals 20b are disposed at a side of bumps 18b so as to extend to the surface that makes contact with printed circuit board 2.

Fitting bumps 18b of lower connector 36b into recesses 18a of upper connector 36a form joint 18. That is, the fit-in engagement between bumps 18b of lower connector 36b and recesses 18a of upper connector 36a establishes connections between printed circuit board 1 (via upper connector 36a) and printed circuit board 2 (via lower connector 36b). Under the state where lower connector 36b fits into upper connector 36a, connection terminals 20a of upper connector 36a make contact with connection terminals 20b of lower connector 36b, allowing the circuits on printed circuit board 1 to have connection to the circuits on printed circuit board 2. Connection terminals 20a and 20b, which are located inside conductors 46a and 46b, respectively, reduces noise caused from conductors disposed inside the connector.

Under the fit-in engagement, projections 19a are inserted into projection sockets 19b. The engagement reinforces the connection between upper connector 36a and lower connector 36b. Disengaging projections 19a from projection sockets 19b separates upper connector 36a from lower connector 36b, that is, the attached two boards are easily divided into each board.

The structure of the embodiment has electric continuity to the ground via projections 19a and projection sockets 19b, which enhances shield effect.

Although recesses 18a are formed on upper connector 36a in the structure of the embodiment, it is not limited thereto. Bumps 18b instead of recesses 18a, or both of them can be formed on upper connector 36a. Furthermore, projections 19a, which are formed on upper connector 36a in the embodiment, can be formed on lower connector 36b.

Compared to an attachment of the connector with a shield and each printed circuit board with a clearance left at a joint section, higher shield effect is expected in a tight attachment with no clearance left.

### Eighth Exemplary Embodiment

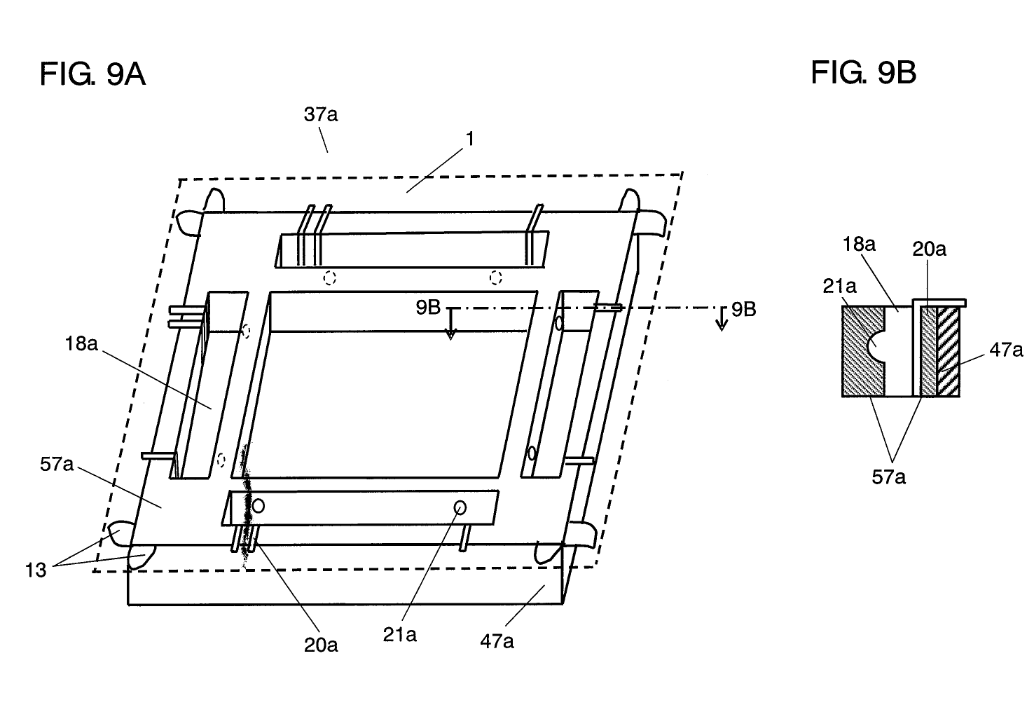

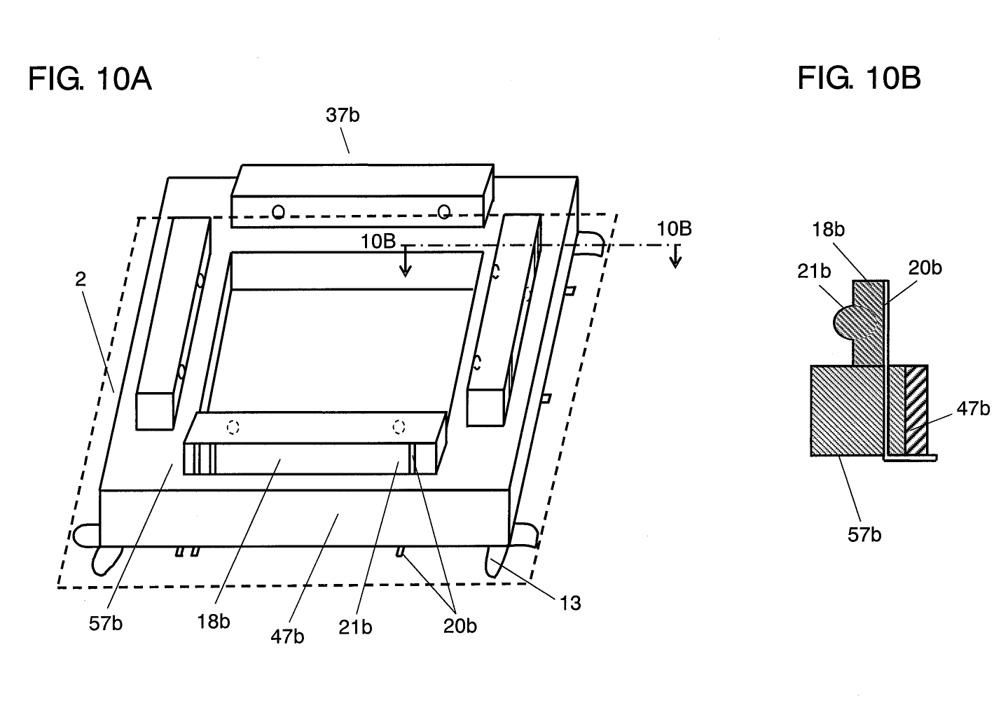

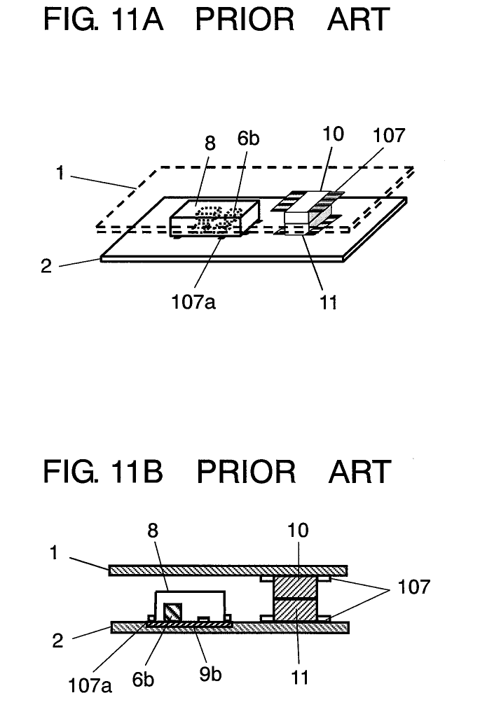

Each of FIGS. 9A and 10A are perspective views and each of FIGS. 9B and 10B are partially shown section views of a connector with a shield in accordance with the eighth exemplary embodiment. The connector with a shield of the embodiment has a structure dividable into the upper half and the lower half. FIGS. 9A and 9B show upper connector 37a and FIGS. 10 A and 10B show lower connector 37b. Upper connector 37a of FIG. 9A, which is made of resin or other insulating materials, has square frame body 57a as a main structure. Conductor 47a is disposed over the outer periphery of frame body 57a.

FIG. 9B is a partially shown section view, taken along line 9B-9B, of upper connector 37a of FIG. 9A. Instead of projections 19a described in the seventh exemplary embodiment, upper connector 37a of FIG. 9B has pits 21a on the wall surface of recesses 18a. Pits 21a serve as a reinforcement member for connecting upper connector 37a to lower connector 37b.

Lower connector 37b of FIG. 10A, which is also made of resin or other insulating materials, has square frame body 57b as a main structure. Conductor 47b is disposed over the outer periphery of frame body 57b.

FIG. 10B is a partially shown section view, taken along line 10B-10B, of lower connector 37b of FIG. 10A. Instead of projection sockets 19b described in the seventh exemplary embodiment, lower connector 37b of FIG. 10B has protrusions 21b on the wall surface of bumps 18b. Protrusions 21b fit with pits 21a and reinforce the attachment of lower connector 37b and upper connector 37a. The rest of the structure is the same as that in the seventh exemplary embodiment.

The structure above provides effect similar to the structure described in the seventh exemplary embodiment. Pits 21a formed on recesses 18a and protrusions 21b formed on bumps 18b enhance a tight contact between connection terminals 20a and 20b; accordingly, provide reliable connections of connection terminals 20a and 20b.

Although pits 21a are formed on upper connector 37a in the embodiment, they can be formed on lower connector 37b.

Compared to an attachment of the connector with a shield and each printed circuit board with a clearance left at a joint section, higher shield effect is expected in a tight attachment with no clearance left.

### INDUSTRIAL APPLICABILITY

The connector with a shield and the circuit board device having the connector of the present invention not only provide a shield and keep electronic parts that can generate noise and an electromagnetic wave therein so as to separate from other components, but also establish connections of circuits between the printed circuit boards. Employing the connector with a shield allows a circuit board device to have compact structure with high flexibility in circuit design. It is therefore suitable for mobile devices, for example, mobile phones and PDAs where downsizing is much-needed, and also suitable for communications device that generate noise and electromagnetic waves.

1. A connector with a shield comprising:
an insulating-material-made frame body that surrounds a predetermined area between a pair of printed circuit boards confronting with each other;
a connection terminal, which is disposed at the frame body, for connecting circuits at the pair of printed circuit boards; and
a conductor disposed at a periphery of the frame body.

2. The connector with a shield according to claim 1, wherein the conductor is disposed at an outer periphery of the frame body, and the connection terminal is disposed at least at one inner side of the frame body.

3. The connector with a shield according to claim 1, wherein the conductor is disposed on an inner periphery of the frame body, and the connection terminal is disposed at least at one outer side of the frame body.

4. The connector with a shield according to claim 1, wherein the conductor is disposed at an outer periphery of the frame body, and the connection terminal is disposed inside the frame body.

5. The connector with a shield according to claim 1, wherein a connection/reinforcement terminal is disposed at least at one side of the conductor so that the pair of printed circuit boards is connected to the frame body with the connection/reinforcement terminal.

6. The connector with a shield according to claim 1, the connection terminal is disposed at least at one side of the frame body so that an inside of the frame body is connected to an outside of the frame body.

7. The connector with a shield according to claim 1, wherein an opening is formed at least at one side of the frame body.

8. The connector with a shield according to claim 1, wherein a notch is formed at least at one side of the frame body.

9. The connector with a shield according to claim 1, wherein the connector with a shield is dividable into an upper piece and a lower piece, and a connection terminal is disposed at a joint section of the upper piece and the lower piece.

10. The connector with a shield according to claim 9, wherein a projection is formed at an outer periphery of one of the divided pieces of the connector with a shield, and a projection socket is formed at an outer periphery of the other piece of the connector with a shield so as to fit with the projection.

11. The connector with a shield according to claim 9, wherein a bump is formed at the joint section one of the divided pieces of the connector with a shield, and a recess is formed at the joint section of the other piece of the connector with a shield so as to fit with the bump.

12. The connector with a shield according to claim 10, wherein a bump is formed at the joint section of one of the divided pieces of the connector with a shield, and a recess is formed at the joint section of the other piece of the connector with a shield so as to fit with the bump.

13. The connector with a shield according to claim 11, wherein a protrusion is formed at a side of the bump or the recess, and a pit is formed at a side of the recess or the bump so as to fit with the projection.

14. The connector with a shield according to claim 12, wherein a projection is formed at a side of the bump or the recess, and a pit is formed at a side of the recess or the bump so as to fit with the projection.

15. A circuit board device comprising:
a ground pattern formed at the pair of printed circuit boards, wherein a shield is formed by using the connector with a shield according to claim 1 so as to surround the ground pattern.

16. The circuit board device according to claim 15, wherein the connector with a shield is connected to the pair of printed circuit boards with.
